(19) United States
(12) Patent Application Publication
(10) Pub. No.: US 2025/0351673 A1
(43) Pub. Date: Nov. 13, 2025

(54) DISPLAY DEVICE AND ELECTRONIC DEVICE INCLUDING THE SAME

(71) Applicant: Samsung Display Co., Ltd., Yongin-Si (KR)

(72) Inventors: Jong Oh SEO, Yongin-si (KR); Dae Soo KIM, Yongin-si (KR); Sang Gab KIM, Yongin-si (KR)

(21) Appl. No.: 19/064,724

(22) Filed: Feb. 27, 2025

(30) Foreign Application Priority Data
May 7, 2024 (KR) 10-2024-0060019

(51) Int. Cl. H10K 59/121; H10D 86/40; H10D 86/60

(52) U.S. Cl. CPC H10K 59/1213; H10D 86/421; H10D 86/60

(57) ABSTRACT

The present disclosure provides a display device which includes a substrate, a first polycrystalline semiconductor on the substrate and including a channel region, a source region, and a drain region of a first transistor, a first silicon oxide film on the first polycrystalline semiconductor, a first gate insulating film on the first silicon oxide film, a gate electrode of the first transistor on the first gate insulating film and overlapping the channel region of the first transistor, and a first interlayer insulating film on the gate electrode of the first transistor. A thickness ratio of the first silicon oxide film and the channel region of the first transistor is 1:13 to 1:16.

### CROSS-REFERENCE TO RELATED APPLICATION

This application claims priority to and the benefit of Korean Patent Application No. 10-2024-0060019 filed in the Korean Intellectual Property Office on May 7, 2024, the entire contents of which are incorporated herein by reference.

### BACKGROUND

### (A) Field

The present disclosure relates to a display device.

### (B) DESCRIPTION OF THE RELATED ART

An organic light-emitting display device includes two electrodes and an organic light emitting layer positioned therebetween, and electrons injected from one electrode and holes injected from the other electrode are combined in the organic light emitting layer to form excitons. The excitons emit light by discharging energy while changing from the exited state to the ground state.

This organic light-emitting display device includes a plurality of pixels including organic light-emitting diodes which are self-luminous devices, and each pixel includes one or more capacitors and a plurality of transistors for driving the organic light-emitting diodes. The plurality of transistors basically includes switching transistors and driving transistors.

As the number of pixels is increased to raise the resolution of the organic light-emitting display device, the areas of the transistors are reduced, and due to an increase in variation in the characteristics of the transistors, characteristic degradation may occur.

### SUMMARY

The present disclosure attempts to remedy defects of polysilicon of transistors, thereby improving the characteristics of a display device that has high resolution and is driven at high speed.

A display device according to an embodiment includes a substrate, a first polycrystalline semiconductor on the substrate and including a channel region, a source region, and a drain region of a first transistor, a first silicon oxide film on the first polycrystalline semiconductor, a first gate insulating film on the first silicon oxide film, a gate electrode of the first transistor on the first gate insulating film and overlapping the channel region of the first transistor, and a first interlayer insulating film on the gate electrode of the first transistor. A thickness ratio of the first silicon oxide film and the channel region of the first transistor may be 1:13 to 1:16.

A g value of the first silicon oxide film measured with an electron spin resonance spectrometer may be equal to or greater than 2.000 and may be smaller than 2.005.

A dangling bond density of silicon of the first silicon oxide film measured with an electron spin resonance spectrometer may be smaller than 1.98×10¹³/cm³.

A surface of the first silicon oxide film may have a surface roughness in which an Rt value may be equal to or greater than 40 nm and may be smaller than 98 nm and an Rq value may be equal to or greater than 8 nm and may be smaller than 19 nm.

A display device according to an embodiment may include a substrate, a first polycrystalline semiconductor on the substrate and including a channel region, a source region, and a drain region of a first transistor, a second polycrystalline semiconductor apart from the first polycrystalline semiconductor on the substrate and including a channel region, a source region, and a drain region of a second transistor, a first silicon oxide film on the first polycrystalline semiconductor, a second silicon oxide film on the second polycrystalline semiconductor, a first gate insulating film on the first silicon oxide film and the second silicon oxide film, a gate electrode of the first transistor on the first gate insulating film and overlapping the channel region of the first transistor, a gate electrode of the second transistor on the first gate insulating film and overlapping the channel region of the second transistor, and a first interlayer insulating film on the gate electrode of the first transistor and the gate electrode of the second transistor. A thickness ratio of the first silicon oxide film and the second silicon oxide film may be 1:0.15 to 1:0.4.

A thickness of the first silicon oxide film may be 2.5 nm to 3.0 nm.

A thickness of the second silicon oxide film may be 0.5 nm to 1.0 nm.

A thickness ratio of the first silicon oxide film and the channel region of the first transistor may be 1:13 to 1:16.

A thickness ratio of the second silicon oxide film and the channel region of the second transistor may be 1:42 to 1:84.

A thickness of the channel region of the first transistor may be 40 nm or less.

A thickness of the channel region of the second transistor may be greater than 40 nm and may be equal to or smaller than 42 nm.

A ratio of a first thickness which is a sum of a thickness of the first silicon oxide film and a thickness of the channel region of the first transistor to a second thickness which is a sum of a thickness of the second silicon oxide film and a thickness of the channel region of the second transistor may be 0.9:1 to 1.1:1.

A g value of the first silicon oxide film measured with an electron spin resonance spectrometer may be equal to or greater than 2.000 and may be smaller than 2.005.

A g value of the second silicon oxide film measured with the electron spin resonance spectrometer may be equal to or greater than 2.005.

A dangling bond density of silicon of the first silicon oxide film measured with an electron spin resonance spectrometer may be smaller than 1.98×10¹³/cm³.

A dangling bond density of silicon of the second silicon oxide film measured with the electron spin resonance spectrometer may be equal to or greater than 1.98×10¹³/cm³.

A surface of the first silicon oxide film may have a surface roughness in which an Rt value may be equal to or greater than 40 nm and may be smaller than 98 nm and an Rq value may be equal to or greater than 8 nm and may be smaller than 19 nm.

The first transistor may be a switching transistor.

The second transistor may be a driving transistor.

The first silicon oxide film may be formed by performing plasma processing on a surface of the first polycrystalline semiconductor under the conditions of a temperature of 200° C. to 300° C. and 45 sec to 240 sec, using hydrogen and hydroxyl radicals (H⁺ and OH⁺) generated by supplying aqueous vapor (H₂O vapor) to a remote plasma ashing apparatus.

The second silicon oxide film may be a native oxide film of a surface of the second polycrystalline semiconductor.

A display device according to an embodiment may include a substrate, a first polycrystalline semiconductor on the substrate and including a channel region, a source region, and a drain region of a first transistor, a first silicon oxide film on the first polycrystalline semiconductor, a first gate insulating film on the first silicon oxide film, a gate electrode of the first transistor on the first gate insulating film and overlapping the channel region of the first transistor, a first interlayer insulating film on the gate electrode of the first transistor, an oxide semiconductor on the first interlayer insulating film, and including a channel region, a source region, and a drain region of a third transistor, a third gate insulating film on the oxide semiconductor, a gate electrode of the third transistor on the third gate insulating film, and overlapping the channel region of the third transistor, and a second interlayer insulating film on the gate electrode of the third transistor. A thickness ratio of the first silicon oxide film and the channel region of the first transistor may be 1:13 to 1:16.

A g value of the first silicon oxide film measured with an electron spin resonance spectrometer may be equal to or greater than 2.000 and may be smaller than 2.005.

A dangling bond density of the silicon of the first silicon oxide film measured with an electron spin resonance spectrometer may be smaller than 1.98×10¹³/cm³.

A surface of the first silicon oxide film has a surface roughness in which an Rt value may be equal to or greater than 40 nm and may be smaller than 98 nm and an Rq value may be equal to or greater than 8 nm and may be smaller than 19 nm.

An electronic device according to an embodiment may include a display device that includes a substrate, a first polycrystalline semiconductor on the substrate and including a channel region, a source region, and a drain region of a first transistor, a first silicon oxide film on the first polycrystalline semiconductor, a first gate insulating film on the first silicon oxide film, a gate electrode of the first transistor on the first gate insulating film and overlapping the channel region of the first transistor, and a first interlayer insulating film on the gate electrode of the first transistor. A thickness ratio of the first silicon oxide film and the channel region of the first transistor may be 1:13 to 1:16.

An electronic device according to an embodiment may include a display device that includes a substrate, a first polycrystalline semiconductor on the substrate and including a channel region, a source region, and a drain region of a first transistor, a second polycrystalline semiconductor apart from the first polycrystalline semiconductor on the substrate and including a channel region, a source region, and a drain region of a second transistor, a first silicon oxide film on the first polycrystalline semiconductor, a second silicon oxide film on the second polycrystalline semiconductor, a first gate insulating film on the first silicon oxide film and the second silicon oxide film, a gate electrode of the first transistor on the first gate insulating film and overlapping the channel region of the first transistor, a gate electrode of the second transistor on the first gate insulating film and overlapping the channel region of the second transistor, and a first interlayer insulating film on the gate electrode of the first transistor and the gate electrode of the second transistor. A thickness ratio of the first silicon oxide film and the second silicon oxide film may be 1:0.15 to 1:0.4.

An electronic device according to an embodiment may include a display device that includes a substrate, a first polycrystalline semiconductor on the substrate and including a channel region, a source region, and a drain region of a first transistor, a first silicon oxide film on the first polycrystalline semiconductor, a first gate insulating film on the first silicon oxide film, a gate electrode of the first transistor on the first gate insulating film and overlapping the channel region of the first transistor, a first interlayer insulating film on the gate electrode of the first transistor, an oxide semiconductor on the first interlayer insulating film, and including a channel region, a source region, and a drain region of a third transistor, a third gate insulating film on the oxide semiconductor, a gate electrode of the third transistor on the third gate insulating film, and overlapping the channel region of the third transistor, and a second interlayer insulating film on the gate electrode of the third transistor. A thickness ratio of the first silicon oxide film and the channel region of the first transistor may be 1:13 to 1:16.

According to the embodiment, it is possible to remedy defects of polysilicon of transistors, thereby improving the characteristics of a display device that has high resolution and is driven at high speed.

### BRIEF DESCRIPTION OF THE DRAWINGS

FIG. 1 is a cross-sectional view illustrating a portion of a display device according to an embodiment.

FIG. 2 is an enlarged cross-sectional view illustrating some portions of a first transistor and a second transistor of the display device according to an embodiment.

FIG. 3 is a graph illustrating the results measured by electron spin resonance spectrometry on silicon oxide films according to embodiments, and a comparative example.

FIG. 4 is an electron micrograph showing the result obtained by measuring the surface roughness of a silicon oxide film according to an embodiment at a magnification of 5 μm.

FIG. 5 is an electron micrograph showing the result obtained by measuring the surface roughness of a first silicon oxide film according to an embodiment at a magnification of 10 μm.

FIG. 6 is an electron micrograph showing the result obtained by measuring the surface roughness of a silicon oxide film according to a comparative example at a magnification of 5 μm.

FIG. 7 is an electron micrograph showing the result obtained by measuring the surface roughness of a first silicon oxide film according to a comparative example at a magnification of 10 μm.

FIG. 8 is a circuit diagram of a display device according to an embodiment.

FIG. 9 is a cross-sectional view illustrating a portion of the display device according to an embodiment.

FIG. 10 is a circuit diagram of a display device according to an embodiment.

FIG. 11 is a block diagram of an electronic device according to an embodiment.

FIGS. 12 to 14 are schematic diagrams of electronic devices according to various embodiments.

### DETAILED DESCRIPTION OF THE EMBODIMENTS

In the following detailed description, only certain embodiments have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. Further, in the drawings, for understanding and ease of description, the thickness of some layers and areas is exaggerated.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

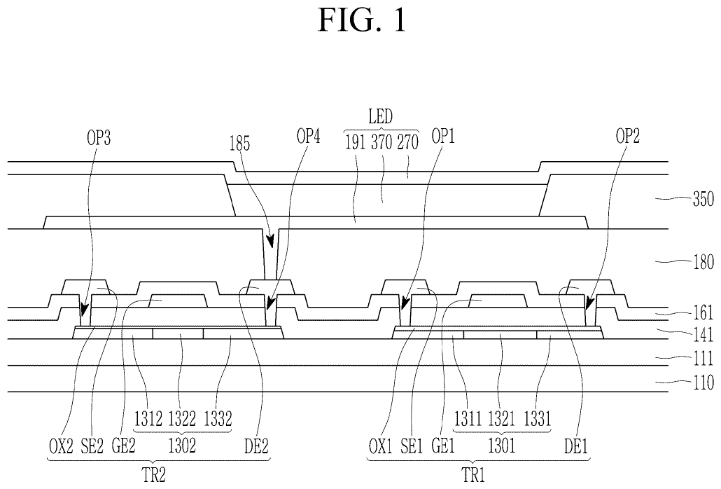

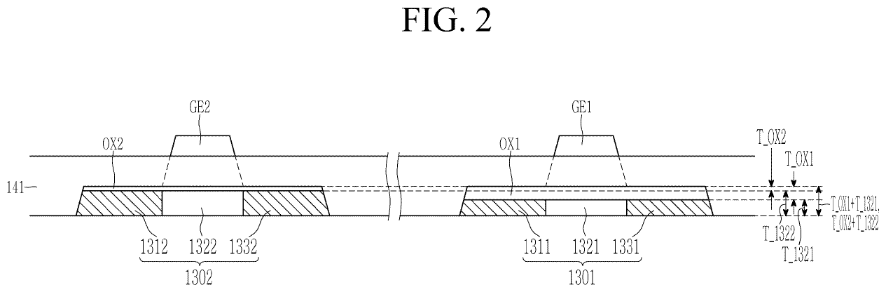

A display device according to an embodiment will be described with reference to FIGS. 1 and 2.

FIG. 1 is a cross-sectional view illustrating a portion of a display device according to an embodiment. FIG. 1 illustrates the display device with a focus on a first transistor TR1, a second transistor TR2, and a light-emitting diode LED connected to the second transistor TR2 for ease of explanation. FIG. 2 is an enlarged cross-sectional view illustrating some portions of the first transistor TR1 and the second transistor TR2 of the display device according to an embodiment. As an example, the first transistor TR1 may be a switching transistor, and the second transistor TR2 may be a driving transistor.

On a substrate 110, a buffer layer 111 may be positioned. The substrate 110 may contain polystyrene, polyvinylalcohol, polymethylmethacrylate, polyethersulfone, polyacrylate, polyetherimide, polyethylene naphthalate, polyethylene terephthalate, polyphenylene sulfide, polyarylate, polyimide, polycarbonate, triacetate cellulose, cellulose acetate propionate), or a combination thereof. The substrate 110 may contain a flexible material which is bendable and foldable, and may be a single layer or multiple layers.

The buffer layer 111 may be a single-layer or multi-layer structure. The buffer layer 111 is illustrated as a single layer in FIG. 1, but may be multiple layers in some embodiments. The buffer layer 111 may contain an organic insulating material or an inorganic insulating material. As an example, the buffer layer 111 may contain silicon nitride, silicon oxide, silicon oxynitride, or a combination thereof.

On the buffer layer 111, a first semiconductor 1301 may be positioned. The first semiconductor 1301 may contain a polysilicon material. That is, the first semiconductor 1301 may comprise a polycrystalline semiconductor, in which case the first semiconductor 1301 may be a first polycrystalline semiconductor. The first semiconductor 1301 may include a source region 1311, a channel region 1321, and a drain region 1331.

The source region 1311 of the first semiconductor 1301 may be connected to a first source electrode SE1 to be described below, and the drain region 1331 of the first semiconductor 1301 may be connected to a first drain electrode DE1 to be described below.

When the first semiconductor 1301 contains a polysilicon material, many defects may occur in the polysilicon during silicon crystallization, and theses defects may degrade the characteristics of the first transistor TR1 and even the lighting characteristics of the panel. In order to raise the resolution of the display device, it is possible to remedy such defects of polysilicon.

For this reason, on the first semiconductor 1301, a first silicon oxide film OX1 may be positioned. The first silicon oxide film OX1 may contain silicon oxide (SiOₓ, wherein 0<x≤3).

As an example, the first silicon oxide film OX1 may be formed using a remote plasma ashing (RPA) apparatus while aqueous vapor (H₂O vapor) is supplied. For example, the first silicon oxide film OX1 may be formed by performing plasma processing on the surface of the first polycrystalline semiconductor, using hydrogen and hydroxyl radicals (H⁺ and OH⁺) generated by supplying aqueous vapor to the remote plasma ashing apparatus, at a temperature of 200° C. to 300° C. for 45 sec to 240 sec.

When the first silicon oxide film OX1 is formed using a remote plasma ashing apparatus while aqueous vapor is supplied, the uniformity of the first silicon oxide film OX1 can be improved due to the use of a multi-array source, especially, in a large area, and the process time is short and a low-temperature process is possible, which help with mass production. Further, since large amounts of hydrogen and hydroxyl radicals (H⁺ and OH⁺) are generated by the aqueous vapor supply, the remote plasma ashing apparatus may reduce damage to the substrate 110 and the like which may be caused in a non-direct plasma manner by the plasma, and H₂O plasma processing may be difficult with general plasma equipment for dry etch and the like. Furthermore, when the first silicon oxide film OX1 is formed in a furnace by thermal processing, the surface roughness of the first silicon oxide film OX1 may increase significantly.

As the first silicon oxide film OX1 is formed using the remote plasma ashing apparatus while aqueous vapor is supplied as described above, it is possible to reduce the dangling bond of the silicon which may act as a defect between the first silicon oxide film and a first gate insulating film 141 to be described below, thereby improving the quality. Accordingly, it is possible to improve the characteristics of the display device having a high resolution.

For example, when the case of using the first transistor TR1 including the first silicon oxide film OX1 formed using the remote plasma ashing apparatus while supplying the aqueous vapor (embodiment 1-1) and a case of using a first transistor TR1 including no first silicon oxide film OX1 (comparative example 1-1) are compared, it is possible to obtain a result that their threshold voltages V_{Th} are −2.61 V and −2.48 V, respectively, so the threshold voltage in embodiment 1-1 is lower, and their hysteresis are 0.24 and 0.18, respectively, so the hysteresis in embodiment 1-1 is lower.

As an example, the thickness T_OX1 of the first silicon oxide film OX1 may be 2.5 nm or greater, for example, 2.6 nm or greater, 2.7 nm or greater, 2.8 nm or greater, or 2.9 nm or greater, and may be 3.0 nm or less, for example, 2.9 nm or less, 2.8 nm or less, 2.7 nm or less, or 2.6 nm or less, or may be 2.5 nm to 3.0 nm. Here, the first silicon oxide film OX1 may have a lower surface which is in contact with the upper surface of the first semiconductor 1301 and an upper surface which is in contact with the lower surface of the first gate insulating film 141. The thickness T_OX1 of the first silicon oxide film OX1 may be the shortest distance between the lower surface and upper surface of the first silicon oxide film OX1.

In the case of forming the first silicon oxide film OX1 using the remote plasma ashing apparatus while supplying aqueous vapor as described above, since the thickness T_OX1 of the first silicon oxide film OX1 is relatively larger than that of a native oxide film, in order to prevent change in characteristics of the display device from being caused by the increased thickness T_OX1 of the first silicon oxide film OX1 and control the variation, it is possible to reduce the thickness T_1321 of the channel region 1321 of the first transistor TR1.

As an example, the thickness T_1321 of the channel region 1321 of the first transistor TR1 may be 40 nm or less, for example, 35 nm or less, 30 nm or less, 25 nm or less, or 20 nm or less, and may be 20 nm or greater, for example, 25 nm or greater, 30 nm or greater, or 35 nm or greater. Here, the channel region 1321 of the first transistor TR1 may have a lower surface which is in contact with the upper surface of the buffer layer 111 and an upper surface which is in contact with the lower surface of the first silicon oxide film OX1. The thickness T_1321 of the channel region 1321 of the first transistor TR1 may be the shortest distance between the lower surface and upper surface of the channel region 1321 of the first transistor TR1.

Accordingly, the thickness ratio of the first silicon oxide film OX1 and the channel region 1321 of the first transistor TR1, i.e., the ratio of the thickness T_OX1 of the first silicon oxide film OX1 to the thickness T_1321 of the channel region 1321 of the first transistor TR1 may be 1:13 or greater, for example, 1:13.5 or greater, 1:14 or greater, 1:14.5 or greater, 1:15 or greater, or 1:15.5 or greater, and may be 1:16 or less, for example, 1:15.5 or less, 1:15 or less, 1:14.5 or less, 1:14 or less, or 1:13.5 or less, and may be 1:13 to 1:16.

Further, as the first silicon oxide film OX1 is formed using the remote plasma ashing apparatus while aqueous vapor is supplied, the g value of the first silicon oxide film OX1 which is measured with an electron spin resonance (ESR) spectrometer may be 2.000 or greater, for example, 2.001 or greater, 2.002 or greater, 2.003 or greater, or 2.004 or greater, and may be smaller than 2.005, for example, 2.004 or less, 2.003 or less, 2.002 or less, or 2.001 or less, and may be equal to or greater than 2.000 and smaller than 2.005.

Furthermore, the dangling bond density of the silicon of the first silicon oxide film OX1 which is measured with an electron spin resonance spectrometer may be smaller than 1.98×10¹³/cm³, for example, 1.90×10¹³/cm³ or less, 1.80×10¹³/cm³ or less, 1.70×10¹³/cm³ or less, 1.60×10¹³/cm³ or less, 1.50×10¹³/cm³ or less, 1.40×10¹³/cm³ or less, 1.30×10¹³/cm³ or less, 1.20×10¹³/cm³ or less, 1.10×10¹³/cm³ or less, 1.00×10¹³/cm³ or less, 9.0×10¹²/cm³ or less, 8.0×10¹²/cm³ or less, 7.0×10¹²/cm³ or less, 6.0×10¹²/cm³ or less, 5.0×10¹²/cm³ or less, 4.0×10¹²/cm³ or less, 3.0×10¹²/cm³ or less, 2.0×10¹²/cm³ or less, or 1.0×10¹²/cm³ or less, and may be 1.0×10¹²/cm³ or greater, or may be 2.0×10¹²/cm³ or greater, 3.0×10¹²/cm³ or greater, 4.0×10¹²/cm³ or greater, 5.0×10¹²/cm³ or greater, 6.0×10¹²/cm³ or greater, 7.0×10¹²/cm³ or greater, 8.0×10¹²/cm³ or greater, 9.0×10¹²/cm³ or greater, 1.00×10¹³/cm³ or greater, 1.10×10¹³/cm³ or greater, 1.20×10¹³/cm³ or greater, 1.30×10¹³/cm³ or greater, 1.40×10¹³/cm³ or greater, 1.50×10¹³/cm³ or greater, 1.60×10¹³/cm³ or greater, 1.70×10¹³/cm³ or greater, 1.80×10¹³/cm³ or greater, or 1.90×10¹³/cm³ or greater.

Here, in the silicon oxide of the first silicon oxide film OX1, the bonded species consisting of silicon atom having dangling bonds and the nearest atoms therefrom is present, the electron spin resonance (ESR) spectrometer may detect the dangling bond due to the bonded species, thereby measuring the g value and dangling bonds of the silicon oxide.

The g value is a value representing the quality of microwave chemical reactions that occur when microwaves act on a substance, and is a numerical value related to the characteristics of the display device. The g value increases as more silicon-silicon bonds increase and decreases as silicon-silicon bonds decrease.

A dangling bond is a chemical bond associated with an atom on the surface of a solid, and is a bond that does not connect that atom to a second atom and faces away from the solid. In other words, a dangling bond represents a silicon atom that is not bonded.

Electron spin resonance (ESR) spectrometry measurement on the first silicon oxide film OX1 may be positioned under the conditions of a temperature of 10 K, a microwave of 9.45 GHz, and a center field of 3365 G±125 G.

The g value may be calculated by substituting the frequency v of the microwave and the resonance magnetic field H (the intersection with an ESR signal baseline) into the following Expression 1.

$$h v = g β H \qquad [ Expression 1 ]$$

In Expression 1, h is a Planck constant, β is a Bohr magneton.

An electron spin resonance (ESR) spectrum is observed as a differential curve, and an absorption curve is obtained by integrating the differential curve once, and a signal strength (area strength) is obtained by integrating the absorption curve once. The number of spins may be calculated from the signal strength, using a reference sample, by the following Expression 2.

$${N}_{( s a m )} = ( {I}_{S} / {I}_{R} ) \times {N}_{( r e f )} \qquad [ Expression 2 ]$$

In Expression 2, N₍ₛₐₘ₎ is the number of spins of a sample, N(ref) is the number of spins of the reference sample, Iₛ is the signal strength of the sample, and IR is the signal strength of the reference sample.

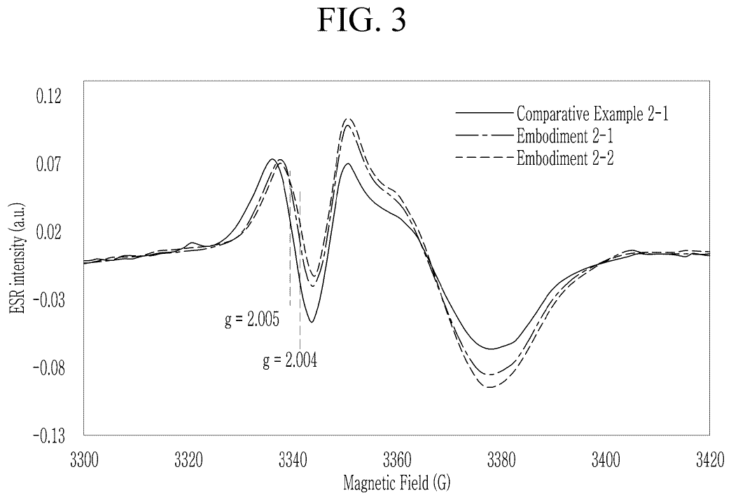

For example, FIG. 3 is a graph illustrating the results obtained by performing electron spin resonance spectrometry measurement on a case of using a first transistor TR1 including a first silicon oxide film OX1 formed under the conditions of 285° C. and 120 sec using a remote plasma ashing apparatus while aqueous vapor was supplied (embodiment 2-1), a case of using a first transistor TR1 including a first silicon oxide film OX1 formed under the conditions of 285° C. and 240 sec (embodiment 2-2), and a case of using a first transistor TR1 including no first silicon oxide film OX1 (comparative example 2-1), and Table 1 sets out the results of FIG. 3.

TABLE 1

| | RPA (H₂O) | g | |
|---|---|---|---|
| | conditions | value | Si dangling bond |
| Comparative Example 2-1 | none | 2.005 | 1.98 × 10¹³/cm³ |
| Embodiment 2-1 | 285° C., 120 sec | 2.004 | 8.05 × 10¹²/cm³ |
| Embodiment 2-2 | 285° C., 240 sec | 2.004 | 8.85 × 10¹²/cm³ |

Referring to FIG. 3 and Table 1, it is possible to obtain the results that in the case of embodiment 2-1, the g value is 2.004 and the dangling bond density is 8.05×10¹²/cm³, and in the case of embodiment 2-2, the g value is 2.004 and the dangling bond density is 8.85×10¹²/cm³, and in the case of comparative example 2-1, the g value is 2.005 and the dangling bond density is 1.98×10¹³/cm³.

Further, as the first silicon oxide film OX1 is formed using the remote plasma ashing apparatus while aqueous vapor is supplied, the surface roughness of the first silicon oxide film OX1 is relatively smaller as compared to the case of forming it through dry etch, chemical vapor deposition (CVD), or thermal processing in a furnace.

As an example, the surface of the first silicon oxide film OX1 has a Rt value which may be 40 nm or greater, for example, 50 nm or greater, 60 nm or greater, 70 nm or greater, 80 nm or greater, or 90 nm or greater, and may be smaller than 98 nm, for example, 90 nm or less, 80 nm or less, 70 nm or less, 60 nm or less, or 50 nm or less, and may be equal to or greater than 40 nm and smaller than 98 nm, and has a Rq value which may be 8 nm or greater, for example, 9 nm or greater, 10 nm or greater, 11 nm or greater, 12 nm or greater, 13 nm or greater, 14 nm or greater, 15 nm or greater, 16 nm or greater, 17 nm or greater, or 18 nm or greater, and may be smaller than 19 nm, for example, 18 nm or less, 17 nm or less, 16 nm or less, 15 nm or less, 14 nm or less, 13 nm or less, 12 nm or less, 11 nm or less, 10 nm or less, or 9 nm or less, and may be equal to or greater than 8 nm and smaller than 19 nm. Here, the Rt value is the maximum roughness depth, and refers to the distance between the highest point and the lowest point within an evaluation length in a roughness profile. The Rq value is the root mean square roughness, and may be calculated by a root-mean-square (rms) method.

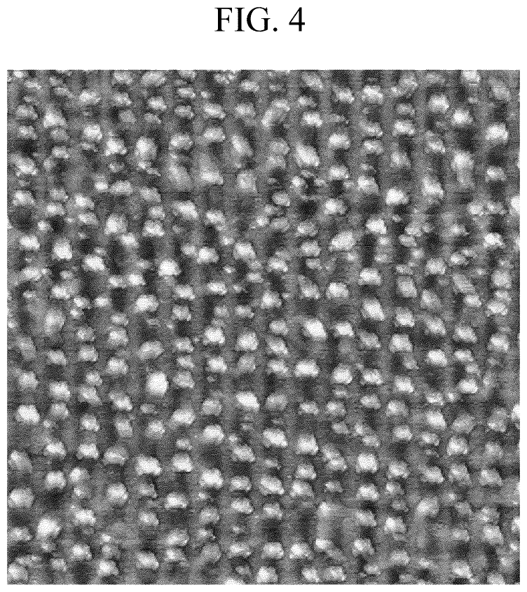

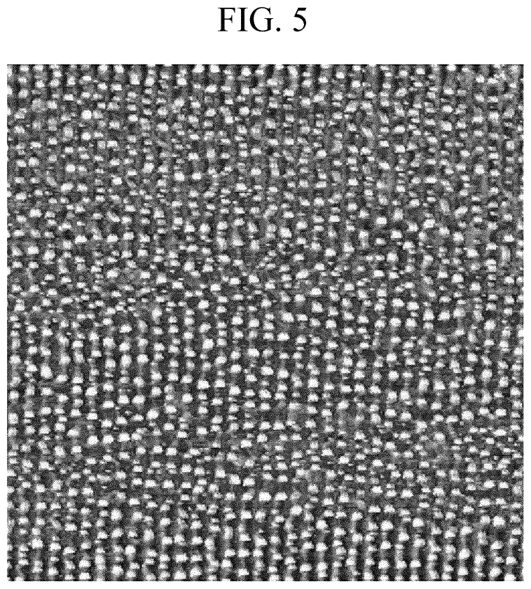

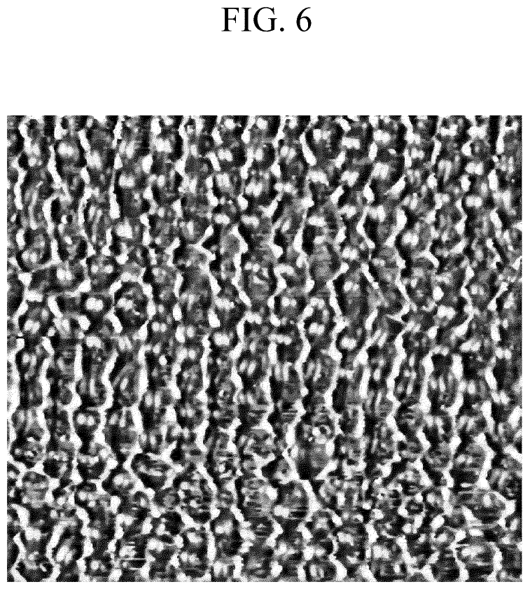

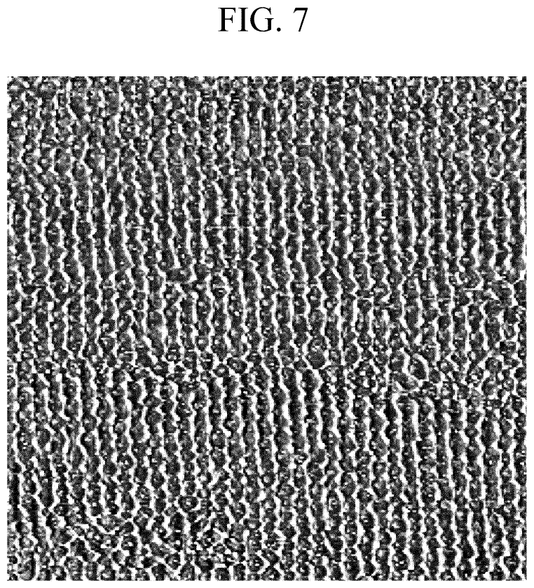

For example, FIGS. 4 and 5 are electron micrographs showing the result obtained by measuring the surface roughness of the first silicon oxide film OX1 formed using the remote plasma ashing apparatus while aqueous vapor was supplied (embodiment 3-1), and FIGS. 6 and 7 are electron micrographs showing the result obtained by measuring the surface roughness of a silicon oxide film formed through thermal processing in a furnace (comparative example 3-1). FIGS. 4 and 6 illustrate the cases in which the magnification is 5 μm, and FIGS. 5 and 7 illustrate the cases in which the magnification is 10 μm. Table 2 sets out the surface roughness measurement results of embodiment 3-1 and comparative example 3-1.

TABLE 2

| | Embodiment 3-1 | Comparative Example 3-1 |
|---|---|---|
| Rt (nm) | 48.1 | 98.4 |
| Rq (nm) | 9.5 | 19.2 |

Referring to FIGS. 4 to 7 and Table 2, it is possible to obtain the result that in the case of embodiment 3-1, the first silicon oxide film OX1 has surface roughness having a Rt value of 48.1 nm and a Rq value of 9.5 nm, whereas in the case of comparative example 3-1, the silicon oxide film has surface roughness having a Rt value of 98.4 nm and a Rq value of 19.2 nm.

On the buffer layer 111, a second semiconductor 1302 may be positioned. The second semiconductor 1302 may contain a polysilicon material. That is, the second semiconductor 1302 may comprise a polycrystalline semiconductor, in which case the second semiconductor 1302 may be a second polycrystalline semiconductor. The second semiconductor 1302 may include a source region 1312, a channel region 1322, and a drain region 1332.

The source region 1312 of the second semiconductor 1302 may be connected to a second source electrode SE2 to be described below, and the drain region 1332 of the second semiconductor 1302 may be connected to a second drain electrode DE2 to be described below.

In some embodiments, on the second semiconductor 1302, a second silicon oxide film OX2 may be positioned. The second silicon oxide film OX2 may contain silicon oxide (SiOₓ, wherein 0<x≤3).

As an example, the second silicon oxide film OX2 may be a native oxide film. In other words, the second silicon oxide film OX2 may not be a film formed using a remote plasma ashing apparatus, unlike the first silicon oxide film OX1. As described above, only the first silicon oxide film OX1 of the first transistor TR1 which is a switching transistor may be formed using the remote plasma ashing apparatus and plasma processing using hydrogen and hydroxyl radicals (H⁺ and OH⁺) may not performed on the second transistor TR2 which is a driving transistor, whereby it is possible to control leakage current loft, improve the mobility, and improve the hysteresis. Accordingly, it is possible to implement small transistors for high resolution.

As an example, the thickness T_OX2 of the second silicon oxide film OX2 may be smaller than the thickness T_OX1 of the first silicon oxide film OX1. The thickness T_OX2 of the second silicon oxide film OX2 may be 0.5 nm or greater, for example, 0.6 nm or greater, 0.7 nm or greater, 0.8 nm or greater, or 0.9 nm or greater, and may be 1.0 nm or less, for example, 0.9 nm or less, 0.8 nm or less, 0.7 nm or less, or 0.6 nm or less, and may be 0.5 nm to 1.0 nm. Here, the second silicon oxide film OX2 may have a lower surface which is in contact with the upper surface of the second semiconductor 1302 and an upper surface which is in contact with the lower surface of the first gate insulating film 141. The thickness T_OX2 of the second silicon oxide film OX2 may be the shortest distance between the lower surface and upper surface of the second silicon oxide film OX2.

Accordingly, the thickness ratio of the first silicon oxide film OX1 and the second silicon oxide film OX2, i.e., the ratio of the thickness T_OX1 of the first silicon oxide film OX1 to the thickness T_OX2 of the second silicon oxide film OX2 may be 1:0.15 or greater, for example, 1:0.2 or greater, 1:0.25 or greater, 1:0.3 or greater, or 1:0.35 or greater, and may be 1:0.4 or less, for example, 1:0.35 or less, 1:0.3 or less, or 1:0.25 or less, and may be 1:0.15 to 1:0.4.

In the case where the second silicon oxide film OX2 is a native oxide film and the first silicon oxide film OX1 is formed using the remote plasma ashing apparatus while aqueous vapor is supplied as described above, since the thickness T_OX1 of the first silicon oxide film OX1 is relatively larger than the thickness T_OX2 of the second silicon oxide film OX2, as described above, in order to prevent change in characteristics of the display device from being caused by the increased thickness T_OX1 of the first silicon oxide film OX1 and control the variation, it is possible to reduce the thickness T_1321 of the channel region 1321 of the first transistor TR1. Accordingly, the thickness T_1322 of the channel region 1322 of the second transistor TR2 may be relatively larger than the thickness T_1321 of the channel region 1321 of the first transistor TR1. As an example, the thickness T_1322 of the channel region 1322 of the second transistor TR2 may exceed 40 nm, for example, 40.5 nm or greater, 41 nm or greater, or 41.5 nm or greater, and may be 42 nm or less, for example, 41.5 nm or less, 41 nm or less, or 40.5 nm or less, and may be greater than 40 nm and equal to or smaller than 42 nm. Here, the channel region 1322 of the second transistor TR2 may have a lower surface which is in contact with the upper surface of the buffer layer 111 and an upper surface which is in contact with the lower surface of the second silicon oxide film OX2. The thickness T_1322 of the channel region 1322 of the second transistor TR2 may be the shortest distance between the lower surface and upper surface of the channel region 1322 of the second transistor TR2.

Accordingly, the thickness ratio of the second silicon oxide film OX2 and the channel region 1322 of the second transistor TR2, i.e., the ratio of the thickness T_OX2 of the second silicon oxide film OX2 to the thickness T_1322 of the channel region 1322 of the second transistor TR2 may be 1:42 or greater, for example, 1:52 or greater, 1:62 or greater, 1:72 or greater, or 1:82 or greater, and may be 1:84 or less, for example, 1:74 or less, 1:64 or less, 1:54 or less, or 1:44 or less, and may be 1:42 to 1:84.

Further, the ratio of a first thickness (T_OX1+T_1321) which is the sum of the thickness T_OX1 of the first silicon oxide film OX1 and the thickness T_1321 of the channel region 1321 of the first transistor TR1 to a second thickness (T_OX2+T_1322) which is the sum of the thickness T_OX2 of the second silicon oxide film OX2 and the thickness T_1322 of the channel region 1322 of the second transistor TR2, i.e., the ratio of the first thickness (T_OX1+T_1321) to the second thickness (T_OX2+T_1322) may be 1:0.9 or greater, for example, 1:1 or greater, or 1:1.1 or greater, and may be 1:1.1 or less, for example, 1:1 or less, or 1:0.9 or less, and may be 0.9:1 to 1.1:1. In the case where the second silicon oxide film OX2 is a native oxide film and the first silicon oxide film OX1 is formed using the remote plasma ashing apparatus while aqueous vapor is supplied as described above, since the thickness T_OX1 of the first silicon oxide film OX1 is relatively larger than the thickness T_OX2 of the second silicon oxide film OX2, in order to prevent change in characteristics of the display device from being caused by the increased thickness T_OX1 of the first silicon oxide film OX1 and control the variation, it is possible to reduce the thickness T_1321 of the channel region 1321 of the first transistor TR1, and accordingly, the first thickness (T_OX1+T_1321) and the second thickness (T_OX2+T_1322) may be substantially the same.

Further, since the second silicon oxide film OX2 is a native oxide film, the g value of the second silicon oxide film OX2 measured with an electron spin resonance (ESR) spectrometer may be 2.005 or greater, for example, 2.006 or greater, 2.007 or greater, or 2.008 or greater, and may be 2.009 or less, for example, 2.008 or less, 2.007 or less, or 2.006 or less.

Furthermore, the dangling bond density of the silicon of the second silicon oxide film OX2 measured with an electron spin resonance spectrometer may be 1.98×10¹³/cm³ or greater, for example, 2.0×10¹³/cm³ or greater, 2.1×10¹³/cm³ or greater, 2.2×10¹³/cm³ or greater, 2.3×10¹³/cm³ or greater, 2.4×10¹³/cm³ or greater, 2.5×10¹³/cm³ or greater, 2.6×10¹³/cm³ or greater, 2.7×10¹³/cm³ or greater, 2.8×10¹³/cm³ or greater, or 2.9×10¹³/cm³ or greater, and may be 3.0×10¹³/cm³ or less, for example, 2.9×10¹³/cm³ or less, 2.8×10¹³/cm³ or less, 2.7×10¹³/cm³ or less, 2.6×10¹³/cm³ or less, 2.5×10¹³/cm³ or less, 2.4×10¹³/cm³ or less, 2.3×10¹³/cm³ or less, 2.2×10¹³/cm³ or less, 2.1×10¹³/cm³ or less, or 2.0×10¹³/cm³ or less.

Here, the measurement conditions and methods of the g value of the second silicon oxide film OX2 and the dangling bonds of the silicon are identical to those described with respect to the first silicon oxide film OX1, and thus a redundant description will not be made.

On the first semiconductor 1301 and the second semiconductor 1302, the first gate insulating film 141 may be positioned. In other words, the first gate insulating film 141 may cover the upper surfaces of the first silicon oxide film OX1 and the second silicon oxide film OX2. The first gate insulating film 141 may contain silicon nitride, silicon oxide, or the like.

On the first gate insulating film 141, a first gate upper electrode GE1 may be positioned. The first gate upper electrode GE1 may overlap the channel region 1321 of the first semiconductor 1301 in the direction perpendicular to the substrate 110.

On the first gate insulating film 141, a second gate upper electrode GE2 may be positioned. The second gate upper electrode GE2 may overlap the channel region 1322 of the second semiconductor 1302 in the direction perpendicular to the substrate 110.

On the first gate insulating film 141, a first interlayer insulating film 161 may be positioned. In other words, the first interlayer insulating film 161 may cover the upper surfaces of a first gate electrode GE1 and a second gate electrode GE2. The first interlayer insulating film 161 may contain silicon nitride, silicon oxide, or the like.

On the first interlayer insulating film 161, the first source electrode SE1, the first drain electrode DE1, the second source electrode SE2, and the second drain electrode DE2 may be positioned. The first gate insulating film 141 and the first interlayer insulating film 161 may have a first opening OP1, a second opening OP2, a third opening OP3, and a fourth opening OP4. The first opening OP1 may overlap the first source electrode SE1, and the second opening OP2 may overlap the first drain electrode DE1. The third opening OP3 may overlap the second source electrode SE2, and the fourth opening OP4 may overlap the second drain electrode DE2.

The first source electrode SE1 may be connected to the source region 1311 of the first semiconductor 1301 through the first opening OP1. The first drain electrode DE1 may be connected to the drain region 1331 of the first semiconductor 1301 through the second opening OP2.

The second source electrode SE2 may be connected to the source region 1312 of the second semiconductor 1302 through the third opening OP3. The second drain electrode DE2 may be connected to the drain region 1332 of the second semiconductor 1302 through the fourth opening OP4.

The first semiconductor 1301, the first gate electrode GE1, the first source electrode SE1, and the first drain electrode DE1 constitute the first transistor TR1. The first transistor TR1 may be a switching transistor, and may include a transistor including a polycrystalline semiconductor.

The second semiconductor 1302, the second gate electrode GE2, the second source electrode SE2, and the second drain electrode DE2 constitute the second transistor TR2. The second transistor TR2 may be a driving transistor connected to the light-emitting diode LED, and may include a transistor including a polycrystalline semiconductor.

On the first source electrode SE1, the first drain electrode DE1, the second source electrode SE2, and the second drain electrode DE2, a third interlayer insulating film 180 may be positioned. The third interlayer insulating film 180 may have an opening 185. The opening 185 of the third interlayer insulating film 180 may overlap the second drain electrode DE2. The third interlayer insulating film 180 may contain silicon nitride, silicon oxide, or the like. In some embodiments, the third interlayer insulating film 180 may include multiple layers in which a layer containing silicon nitride and a layer containing silicon oxide are stacked. In this case, in the third interlayer insulating film 180, the layer containing silicon nitride may be positioned closer to the substrate 110 than the layer containing silicon oxide.

On the third interlayer insulating film 180, an anode 191 may be positioned. The anode 191 may be connected to the second drain electrode DE2 through the opening 185 of the third interlayer insulating film 180.

On the anode 191, a partition 350 may be positioned. The partition 350 may have an opening, and the opening of the partition 350 may overlap the anode 191. Inside the opening of the partition 350, a light-emitting device layer 370 may be positioned.

On the light-emitting device layer 370 and the partition 350, a cathode 270 may be positioned. The anode 191, the light-emitting device layer 370, and the cathode 270 constitute the light-emitting diode LED.

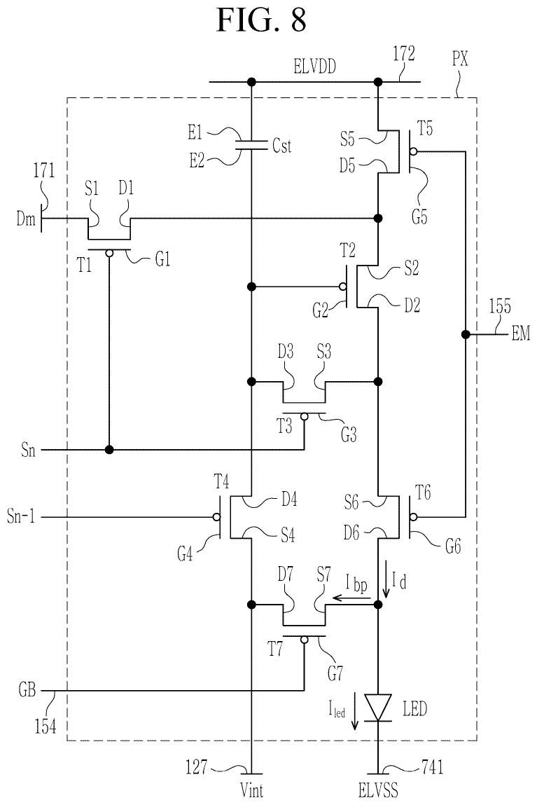

Hereinafter, a circuit diagram of the display device according to an embodiment will be described. FIG. 8 is a circuit diagram of the display device according to the embodiment.

Referring to FIG. 8, one pixel PX of a display device according to an embodiment includes a plurality of transistors T1, T2, T3, T4, T5, T6, and T7, a storage capacitor Cst, and a light-emitting diode LED which are connected to multiple signal lines.

The display device according to the embodiment includes a display area on which images are displayed, and in the display area, such pixels PX are arranged in various forms.

The plurality of transistors T1, T2, T3, T4, T5, T6, and T7 includes a driving transistor T2, and includes switching transistors connected to a scan line Sn, i.e., the first transistor T1 and the third transistor T3, and the other transistors may be transistors for performing operations helpful to operate the light-emitting diode LED (hereinafter, referred to as compensation transistors). These compensation transistors T4, T5, T6, and T7 may include the fourth transistor T4, the fifth transistor T5, the sixth transistor T6, and the seventh transistor T7.

A plurality of signal lines may include the scan line Sn, a previous-stage scan line Sn-1, a light emission control line 155, a bypass control line 154, a data line 171, a driving voltage line 172, an initialization voltage line 127, and a common voltage line 741. The bypass control line 154 may be a portion of the previous-stage scan line Sn-1, or may be electrically connected thereto. In an embodiment, the bypass control line 154 may be a portion of the scan line Sn, or may be electrically connected thereto.

The scan line Sn is connected to a gate driver, and transfers a scan signal to the first transistor T1 and the third transistor T3. The previous-stage scan line Sn-1 is connected to the gate driver, and transfers a previous-stage scan signal, applied to a pixel PX positioned at the previous stage, to the fourth transistor T4. The light emission control line 155 is connected to a light emission controller, and transfers a light emission control signal for controlling the time for which the light-emitting diode LED will emit light, to the fifth transistor T5 and the sixth transistor T6. The bypass control line 154 transfers a bypass signal to the seventh transistor T7.

The data line 171 is a line for transferring a data voltage which is generated by a data driver, and the luminance at which the light-emitting diode LED emits light varies depending on the data voltage. The driving voltage line 172 applies a driving voltage. The initialization voltage line 127 transfers an initialization voltage for initializing the driving transistor T2. The common voltage line 741 applies a common voltage. Each of the voltages which are applied to the driving voltage line 172, the initialization voltage line 127, and the common voltage line 741 may be constant.

Hereinafter, the plurality of transistors T1 to T7 will be described.

The driving transistor T2 is a transistor which adjusts the magnitude of the current to be output, depending on the data voltage which is applied. Driving current Id which is output is applied to the light-emitting diode LED to adjust the brightness of the light-emitting diode LED according to the data voltage. To this end, a first electrode S2 of the driving transistor T2 is disposed so as to be able to receive the driving voltage. The first electrode S2 is connected to the driving voltage line 172 through the fifth transistor T5. Also, the first electrode S2 of the driving transistor T2 is connected to a second electrode D1 of the first transistor T1 and receives the data voltage. A second electrode D2 (output electrode) of the driving transistor T2 is disposed so as to be able to output current toward the light-emitting diode LED. The second electrode D2 of the driving transistor T2 is connected to the anode of the light-emitting diode LED through the sixth transistor T6. A gate electrode G2 is connected to one electrode (a second storage electrode E2) of the storage capacitor Cst. Therefore, depending on the voltage stored in the storage capacitor Cst, the voltage of the gate electrode G2 varies, and accordingly, the driving current Id which the driving transistor T2 outputs is changed.

The first transistor T1 is a transistor which receives the data voltage into the pixel PX. The gate electrode G1 is connected to the scan line Sn, and a first electrode S1 is connected to the data line 171. The second electrode D1 of the first transistor T1 is connected to the first electrode S2 of the driving transistor T2. When the first transistor T1 is turned on in response to the scan signal which is transferred through the scan line Sn, the data voltage which is transferred through the data line 171 is transferred to the first electrode S2 of the driving transistor T2.

The third transistor T3 is a transistor that enables a compensation voltage to which the data voltage has been changed through the driving transistor T2, to be transferred to a second storage electrode E2 of the storage capacitor Cst. A gate electrode G3 is connected to the scan line Sn, and a first electrode S3 is connected to the second electrode D2 of the driving transistor T2. A second electrode D3 of the third transistor T3 is connected to the second storage electrode E2 of the storage capacitor Cst and a gate electrode G2 of the driving transistor T2. The third transistor T3 is turned on in response to the scan signal received through the scan line Sn, thereby connecting the second electrode D2 and the gate electrode G2 of the driving transistor T2 and connecting the second electrode D2 of the driving transistor T2 and the second storage electrode E2 of the storage capacitor Cst.

The fourth transistor T4 serves to initialize the gate electrode G2 of the driving transistor T2 and the second storage electrode E2 of the storage capacitor Cst. A gate electrode G4 is connected to the previous-stage scan line Sn-1, and a first electrode S4 is connected to the initialization voltage line 127. A second electrode D4 of the fourth transistor T4 is connected to the second storage electrode E2 of the storage capacitor Cst and the gate electrode G2 of the driving transistor T2. The fourth transistor T4 transfers the initialization voltage to the gate electrode G2 of the driving transistor T2 and the second storage electrode E2 of the storage capacitor Cst in response to a previous-stage scan signal received through the previous-stage scan line Sn-1. Accordingly, the gate voltage of the gate electrode G2 of the driving transistor T2 and the storage capacitor Cst are initialized. The initialization voltage may be a voltage which has a low voltage value and can turn on the driving transistor T2.

The fifth transistor T5 serves to transfer the driving voltage the driving transistor T2. A gate electrode G5 is connected to the light emission control line 155, and a first electrode S5 is connected to the driving voltage line 172. A second electrode D5 of the fifth transistor T5 is connected to the first electrode S2 of the driving transistor T2.

The sixth transistor T6 serves to transfer the driving current Id which is output from the driving transistor T2 to the light-emitting diode LED. A gate electrode G6 is connected to the light emission control line 155, and a first electrode S6 is connected to the second electrode D2 of the driving transistor T2. A second electrode D6 of the sixth transistor T6 is connected to the anode of the light-emitting diode LED.

The fifth transistor T5 and the sixth transistor T6 are turned on simultaneously in response to the light emission control signal received through the light emission control line 155, and when the driving voltage is applied to the first electrode S2 of the driving transistor T2 through the fifth transistor T5, the driving current Id of the driving transistor T2 is output in response to the voltage of the gate electrode G2 of the driving transistor T2 (i.e., the voltage of the second storage electrode E2 of the storage capacitor Cst). The output driving current Id is transferred to the light-emitting diode LED through the sixth transistor T6. As current lied flows in the light-emitting diode LED, the light-emitting diode LED emits light.

The seventh transistor T7 serves to initialize the anode of the light-emitting diode LED. A gate electrode G7 is connected to the bypass control line 154, and a first electrode S7 is connected to the anode of the light-emitting diode LED, and a second electrode D7 is connected to the initialization voltage line 127. The bypass control line 154 may be connected to the previous-stage scan line Sn-1, and the bypass signal is applied at the same timing as that of the previous-stage scan signal. The bypass control line 154 may not be connected to the previous-stage scan line Sn-1 and transfer a signal separate from the previous-stage scan signal. When the seventh transistor T7 is turned on in response to a bypass signal GB, the initialization voltage is applied to the anode of the light-emitting diode LED such that it is initialized.

A first storage electrode E1 of the storage capacitor Cst is connected to the driving voltage line 172, and the second storage electrode E2 is connected to the gate electrode G2 of the driving transistor T2, the second electrode D3 of the third transistor T3, and the second electrode D4 of the fourth transistor T4. As a result, the second storage electrode E2 determines the voltage of the gate electrode G2 of the driving transistor T2, and receives the data voltage through the second electrode D3 of the third transistor T3, or receives the initialization voltage through the second electrode D4 of the fourth transistor T4.

The anode of the light-emitting diode LED is connected to the second electrode D6 of the sixth transistor T6 and the first electrode S7 of the seventh transistor T7, and the cathode is connected to the common voltage line 741 which transfers the common voltage.

Although it has been described above that one pixel includes seven transistors T1 to T7 and one storage capacitor Cst, the present disclosure is not limited thereto, and the number of transistors, the number of capacitors, and the connection relationship of them may be variously changed.

As an example, the first transistor T1 or the third transistor T3 which is a switching transistor may be positioned on the first polycrystalline semiconductor and include a first silicon oxide film OX1 formed using the remote plasma ashing apparatus while aqueous vapor were supplied, and the second transistor T2 which is a driving transistor may be positioned on the second polycrystalline semiconductor and include a second silicon oxide film OX2 which is a native oxide film.

Each of the third transistor T3, the fourth transistor T4, the fifth transistor T5, the sixth transistor T6, and the seventh transistor T7 may include a polycrystalline semiconductor. The third transistor T3, the fourth transistor T4, the fifth transistor T5, the sixth transistor T6, and the seventh transistor T7 may structures similar to that of the first transistor T1 or the second transistor T2 in the above embodiment. In other words, each of the third transistor T3, the fourth transistor T4, the fifth transistor T5, the sixth transistor T6, and the seventh transistor T7 may be positioned on a polycrystalline semiconductor, and include a first silicon oxide film OX1 formed using the remote plasma ashing apparatus while aqueous vapor was supplied. In an embodiment, each of the third transistor T3, the fourth transistor T4, the fifth transistor T5, the sixth transistor T6, and the seventh transistor T7 may be positioned on a polycrystalline semiconductor, and include a second silicon oxide film OX2 which is a native oxide film. In an embodiment, the third transistor T3, the fourth transistor T4, the fifth transistor T5, the sixth transistor T6, and the seventh transistor T7 may include no first silicon oxide film OX1 and no second silicon oxide film OX2.

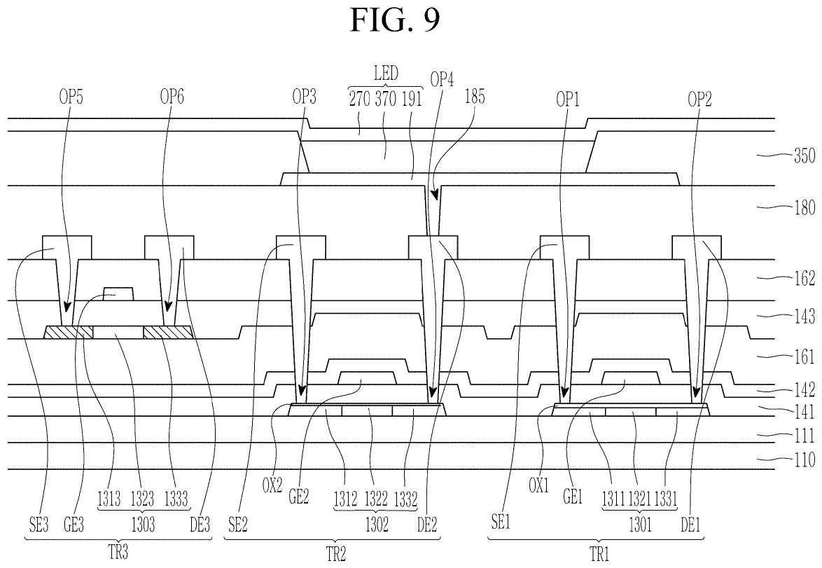

A display device according to an embodiment will be described with reference to FIG. 9.

A display device according to an embodiment shown in FIG. 9 has many parts identical to those of the display device according to the embodiment shown in FIG. 1, and thus a description of the identical parts will not be made. FIG. 9 is different from the previous embodiment in that it shows three transistors, and will be further described below.

FIG. 9 is a cross-sectional view illustrating a portion of the display device according to the embodiment. FIG. 9 illustrating the display device with a focus on a first transistor TR1, a second transistor TR2, a third transistor T3, and a light-emitting diode LED connected to the second transistor TR2 for ease of explanation. The first transistor T1 may be a switching transistor. The second transistor TR2 may be a driving transistor. The third transistor TR3 may be a driving transistor, a switching transistor, or a compensation transistor.

On a substrate 110, a buffer layer 111 may be positioned.

On the buffer layer 111, a first semiconductor 1301 may be positioned. The first semiconductor 1301 may contain a polysilicon material. That is, the first semiconductor 1301 may include a polycrystalline semiconductor, in which case the first semiconductor 1301 may be a first polycrystalline semiconductor. The first semiconductor 1301 may include a source region 1311, a channel region 1321, and a drain region 1331.

The source region 1311 of the first semiconductor 1301 may be connected to a first source electrode SE1, and the drain region 1331 of the first semiconductor 1301 may be connected to a first drain electrode DE1.

On the first semiconductor 1301, a first silicon oxide film OX1 may be positioned. As an example, the first silicon oxide film OX1 may be formed using a remote plasma ashing (RPA) apparatus while aqueous vapor (H₂O vapor) is supplied.

On the buffer layer 111, a second semiconductor 1302 may be positioned. The second semiconductor 1302 may contain a polysilicon material. That is, the second semiconductor 1302 may include a polycrystalline semiconductor, in which case the second semiconductor 1302 may be a second polycrystalline semiconductor. The second semiconductor 1302 may include a source region 1312, a channel region 1322, and a drain region 1332.

The source region 1312 of the second semiconductor 1302 may be connected to the second source electrode SE2, and the drain region 1332 of the second semiconductor 1302 may be connected to the second drain electrode DE2.

In some embodiments, on the second semiconductor 1302, a second silicon oxide film OX2 may be positioned. As an example, the second silicon oxide film OX2 may be a native oxide film.

On the first semiconductor 1301 and the second semiconductor 1302, the first gate insulating film 141 may be positioned. In other words, the first gate insulating film 141 may cover the upper surfaces of the first silicon oxide film OX1 and the second silicon oxide film OX2.

On the first gate insulating film 141, a first gate upper electrode GE1 may be positioned. The first gate upper electrode GE1 may overlap the channel region 1321 of the first semiconductor 1301 in the direction perpendicular to the substrate 110.

On the first gate insulating film 141, a second gate upper electrode GE2 may be positioned. The second gate upper electrode GE2 may overlap the channel region 1322 of the second semiconductor 1302 in the direction perpendicular to the substrate 110.

On the first gate insulating film 141, a second gate insulating film 142 may be positioned, and on the second gate insulating film 142, a first interlayer insulating film 161 may be positioned. In other words, the second gate insulating film 142 and the first interlayer insulating film 161 may cover the upper surfaces of a first gate electrode GE1 and a second gate electrode GE2.

On the first interlayer insulating film 161, a third semiconductor 1303 may be positioned.

The third semiconductor 1303 may include an oxide semiconductor. The oxide semiconductor may contain at least one of one-component metal oxides such as indium oxides (In), tin oxides (Sn), or zinc oxides (Zn), two-component metal oxides such as In—Zn-based oxides, Sn—Zn-based oxides, Al—Zn-based oxides, Zn—Mg-based oxides, Sn—Mg-based oxides, In—Mg-based oxides, or In—Ga-based oxides, three-component metal oxides such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and four-component metal oxides such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides. For example, the third semiconductor 1303 may contain Indium-Gallium-Zinc oxide (IGZO) among the In—Ga—Zn-based oxides.

The third semiconductor 1303 may include a source region 1313, a channel region 1323, and a drain region 1333. The source region 1313 of the third semiconductor 1303 may be connected to a third source electrode SE3 to be described below, and the drain region 1333 of the third semiconductor 1303 may be connected to a third drain electrode DE3 to be described below.

On the third semiconductor 1303, a third gate insulating film 143 may be positioned. In the embodiment of FIG. 9, the third gate insulating film 143 may be positioned over the whole upper surfaces of the third semiconductor 1303 and the first interlayer insulating film 161. Accordingly, the third gate insulating film 143 may cover the upper surfaces and side surfaces of the source region 1313, channel region 1323, and drain region 1333 of the third semiconductor 1303. However, the present disclosure is not limited thereto, and the third gate insulating film 143 may not be positioned on the entire upper surfaces of the third semiconductor 1303 and the first interlayer insulating film 161. For example, the third gate insulating film 143 may be positioned only between a third gate electrode GE3 and the third semiconductor 1303. In other words, the third gate insulating film 143 may overlap the channel region 1323 of the third semiconductor 1303 and may not overlap the source region 1313 and the drain region 1333.

On the third gate insulating film 143, the third gate electrode GE3 may be positioned. The third gate electrode GE3 may overlap the channel region 1323 of the third semiconductor 1303 in the direction perpendicular to the substrate 110.

On the third gate electrode GE3, a second interlayer insulating film 162 may be positioned. On the second interlayer insulating film 162, the first source electrode SE1, the first drain electrode DE1, the second source electrode SE2, the second drain electrode DE2, the third source electrode SE3, and the third drain electrode DE3 may be positioned.

The second interlayer insulating film 162 may have a first opening OP1, a second opening OP2, a third opening OP3, a fourth opening OP4, a fifth opening OP5, and a sixth opening OP6. The first opening OP1 may overlap the first source electrode SE1, and the second opening OP2 may overlap the first drain electrode DE1. The third opening OP3 may overlap the second source electrode SE2, and the fourth opening OP4 may overlap the second drain electrode DE2. The fifth opening OP5 may overlap the third source electrode SE3, and the sixth opening OP6 may overlap the third drain electrode DE3.

The first source electrode SE1 may be connected to the source region 1311 of the first semiconductor 1301 through the first opening OP1. The first drain electrode DE1 may be connected to the drain region 1331 of the first semiconductor 1301 through the second opening OP2.

The second source electrode SE2 may be connected to the source region 1312 of the second semiconductor 1302 through the third opening OP3. The second drain electrode DE2 may be connected to the drain region 1332 of the second semiconductor 1302 through the fourth opening OP4.

The third source electrode SE3 may be connected to the source region 1313 of the third semiconductor 1303 through the fifth opening OP5. The third drain electrode DE3 may be connected to the drain region 1333 of the third semiconductor 1303 through the sixth opening OP6.

The first semiconductor 1301, the first gate electrode GE1, the first source electrode SE1, and the first drain electrode DE1 constitute the first transistor TR1. The first transistor T1 may be a switching transistor, and may include a transistor including a first polycrystalline semiconductor.

The second semiconductor 1302, the second gate electrode GE2, the second source electrode SE2, and the second drain electrode DE2 constitute the second transistor TR2. The second transistor TR2 may be a driving transistor connected to the light-emitting diode LED, and may include a transistor including a second polycrystalline semiconductor.

The third semiconductor 1303, the third gate electrode GE3, the third source electrode SE3, and the third drain electrode DE3 constitute the third transistor T3. The third transistor T3 may be a driving transistor, a switching transistor, or a compensation transistor, and may include a transistor including an oxide semiconductor.

On the first source electrode SE1, the first drain electrode DE1, the second source electrode SE2, the second drain electrode DE2, the third source electrode SE3, and the third drain electrode DE3, the third interlayer insulating film 180 may be positioned. The third interlayer insulating film 180 may have an opening 185. The opening 185 of the third interlayer insulating film 180 may overlap the second drain electrode DE2. The third interlayer insulating film 180 may contain silicon nitride, silicon oxide, or the like. In some embodiments, the third interlayer insulating film 180 may include multiple layers in which a layer containing silicon nitride and a layer containing silicon oxide are stacked. In this case, in the third interlayer insulating film 180, the layer containing silicon nitride may be positioned closer to the substrate 110 than the layer containing silicon oxide.

On the third interlayer insulating film 180, an anode 191 may be positioned. The anode 191 may be connected to the second drain electrode DE2 through the opening 185 of the third interlayer insulating film 180.

On the anode 191, a partition 350 may be positioned. The partition 350 may have an opening, and the opening of the partition 350 may overlap the anode 191. Inside the opening of the partition 350, a light-emitting device layer 370 may be positioned.

On the light-emitting device layer 370 and the partition 350, a cathode 270 may be positioned. The anode 191, the light-emitting device layer 370, and the cathode 270 constitute the light-emitting diode LED.

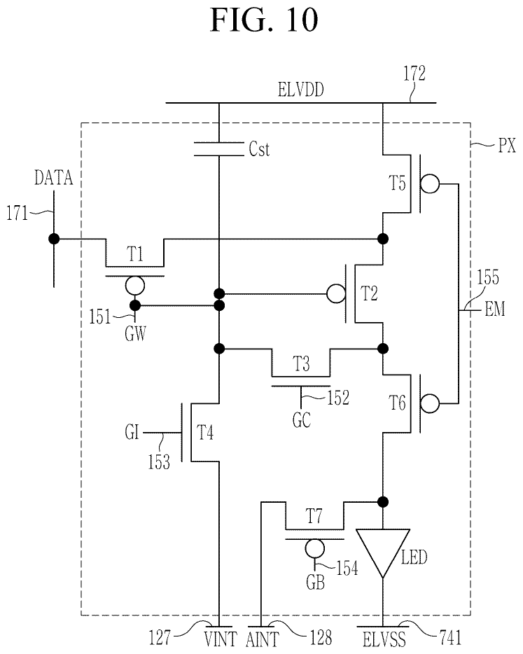

Hereinafter, a circuit diagram of the display device according to the embodiment will be described. FIG. 10 is a circuit diagram of the display device according to the embodiment.

Referring to FIG. 10, one pixel PX of a display device according to an embodiment includes a plurality of transistors T1, T2, T3, T4, T5, T6, and T7, a storage capacitor Cst, and a light-emitting diode LED which are connected to multiple signal lines.

The display device according to the embodiment includes a display area on which images are displayed, and in the display area, such pixels PX are arranged in various forms.

One pixel PX is connected to a plurality of signal lines 127, 128, 151, 152, 153, 154, 155, 171, 172, and 741. The plurality of signal lines 127, 128, 151, 152, 153, 154, 155, 171, 172, and 741 includes a first initialization voltage line 127, a second initialization voltage line 128, a scan line 151, an inversion scan line 152, an initialization control line 153, a bypass control line 154, a light emission control line 155, a data line 171, a driving voltage line 172, and a common voltage line 741.

The scan line 151 is connected to a gate driver (not shown in the drawing) and transfers a scan signal GW to the first transistor T1. The inversion scan line 152 may receive a voltage having the opposite polarity to that of the voltage, which is applied to the scan line 151, at the same timing as that of the signal of the scan line 151. For example, when a high voltage is applied to the scan line 151, a low voltage may be applied to the inversion scan line 152. The inversion scan line 152 transfers an inversion scan signal GC to the third transistor T3.

The initialization control line 153 transfers an initialization control signal GI to the fourth transistor T4. The bypass control line 154 transfers a bypass signal GB to the seventh transistor T7. The bypass control line 154 may include a next-stage scan line 151. The light emission control line 155 transfers a light emission control signal EM to the fifth transistor T5 and the sixth transistor T6.

The data line 171 is a line for transferring a data voltage DATA which is generated by a data driver (not shown in the drawing), and the luminance at which the light-emitting diode LED emits light varies depending on the data voltage DATA which is applied to the pixel PX.

The driving voltage line 172 applies a driving voltage ELVDD. The first initialization voltage line 127 transfers a first initialization voltage VINT, and the second initialization voltage line 128 transfers a second initialization voltage AlNT. The common voltage line 741 applies a common voltage ELVSS to the cathode of the light-emitting diode LED. In the present embodiment, each of the voltages which are applied to the driving voltage line 172, the first and second initialization voltage lines 127 and 128, and the common voltage line 741 may be a constant voltage.

Hereinafter, the structures and connection relationship of the plurality of transistors will be described in detail.

The driving transistor T2 may have p-type transistor characteristics, and may include a polycrystalline semiconductor. Also, the driving transistor T2 may be positioned on a polycrystalline semiconductor and include a second silicon oxide film OX2 which is a native oxide film.

The driving transistor T2 is a transistor which adjusts the magnitude of current to be output to the anode of the light-emitting diode LED, depending on the data voltage DATA which is applied to the gate electrode. Since the brightness of the light-emitting diode LED is adjusted according to the magnitude of the driving current which is output to the anode of the light-emitting diode LED, it is possible to adjust the luminance of the light-emitting diode LED according to the data voltage DATA which is applied to the pixel PX. To this end, the first electrode of the driving transistor T2 may be disposed so as to be able to receive the driving voltage ELVDD, and is connected to the driving voltage line 172 through the fifth transistor T5. Also, the first electrode of the driving transistor T2 is connected to the second electrode of the first transistor T1 to receive the data voltage DATA. The second electrode of the driving transistor T2 is disposed to be able to output current toward the light-emitting diode LED, and is connected to the anode of the light-emitting diode LED through the sixth transistor T6. Also, the second electrode of the driving transistor T2 transfers the data voltage DATA which is applied to the first electrode, to the third transistor T3. The gate electrode of the driving transistor T2 is connected to one electrode of the storage capacitor Cst (hereinafter, referred to as the second storage electrode). Therefore, depending on the voltage stored in the storage capacitor Cst, the voltage of the gate electrode of the driving transistor T2 varies, and accordingly, the driving current which the driving transistor T2 outputs is changed. Also, the storage capacitor Cst serves to maintain the voltage of the gate electrode of the driving transistor T2 constant for one frame.

The first transistor T1 may have p-type transistor characteristics, and may include a polycrystalline semiconductor. Also, the first transistor T1 which is a switching transistor may be positioned on a polycrystalline semiconductor, and include the first silicon oxide film OX1 formed using the remote plasma ashing apparatus while aqueous vapor was supplied.

The first transistor T1 is a transistor which receives the data voltage DATA into the pixel PX. The gate electrode of the first transistor T1 is connected to the scan line 151. The first electrode of the first transistor T1 is connected to the data line 171. The second electrode of the first transistor T1 is connected to the first electrode of the driving transistor T2. When the first transistor T1 is turned on by a low voltage of the scan signal GW which is transferred through the scan line 151, the data voltage DATA which is transferred through the data line 171 is transferred to the first electrode of the driving transistor T2.

The third transistor T3 may have n-type transistor characteristics, and may include an oxide semiconductor. The third transistor T3 electrically connects the second electrode of the driving transistor T2 and the gate electrode of the driving transistor T2. Accordingly, the third transistor is a transistor which enables a compensation voltage to which the data voltage DATA has been changed through the driving transistor T2 to be transferred to the second storage electrode of the storage capacitor Cst. The gate electrode of the third transistor T3 is connected to the inversion scan line 152, and the first electrode of the third transistor T3 is connected to the second electrode of the driving transistor T2. The second electrode of the third transistor T3 is connected to the second storage electrode of the storage capacitor Cst and the gate electrode of the driving transistor T2. The third transistor T3 is turned on by a high voltage of the inversion scan signal GC received through the inversion scan line 152, thereby connecting the gate electrode of the driving transistor T2 and the second electrode of the driving transistor T2 and transferring the voltage applied to the gate electrode of the driving transistor T2 to the second storage electrode of the storage capacitor Cst such that the voltage is stored in the storage capacitor Cst.

The fourth transistor T4 may have n-type transistor characteristics, and may include an oxide semiconductor. The fourth transistor T4 serves to initialize the gate electrode of the driving transistor T2 and the second storage electrode of the storage capacitor Cst. The gate electrode of the fourth transistor T4 is connected to the initialization control line 153, and the first electrode of the fourth transistor T4 is connected to the first initialization voltage line 127. The second electrode of the fourth transistor T4 is connected to the second storage electrode of the storage capacitor Cst and the gate electrode of the driving transistor T2. The fourth transistor T4 is turned on by the high voltage of the initialization control signal GI received through the initialization control line 153, in which case it transfers the first initialization voltage VINT to the gate electrode of the driving transistor T2 and the second storage electrode of the storage capacitor Cst. Accordingly, the voltage of the gate electrode of the driving transistor T2 and the storage capacitor Cst are initialized.

The fifth transistor T5 may have p-type transistor characteristics, and may include a polycrystalline semiconductor. The fifth transistor T5 may be positioned on a polycrystalline semiconductor, and include the first silicon oxide film OX1 formed using the remote plasma ashing apparatus while aqueous vapor was supplied. In an embodiment, the fifth transistor T5 may be positioned on the polycrystalline semiconductor and include a second silicon oxide film OX2 which is a native oxide film. In an embodiment, the fifth transistor T5 may include no first silicon oxide film OX1 and no second silicon oxide film OX2.

The fifth transistor T5 serves to transfer the driving voltage ELVDD to the driving transistor T2. The gate electrode of the fifth transistor T5 is connected to the light emission control line 155, and the first electrode of the fifth transistor T5 is connected to the driving voltage line 172, and the second electrode of the fifth transistor T5 is connected to the first electrode of the driving transistor T2.

The sixth transistor T6 may have p-type transistor characteristics, and may include a polycrystalline semiconductor. The sixth transistor T6 may be positioned on a polycrystalline semiconductor, and include a first silicon oxide film OX1 formed using the remote plasma ashing apparatus while aqueous vapor was supplied. In an embodiment, the sixth transistor T6 may be positioned on a polycrystalline semiconductor, and include a second silicon oxide film OX2 which is a native oxide film. In an embodiment, the sixth transistor T6 may include no first silicon oxide film OX1 and no second silicon oxide film OX2.

The sixth transistor T6 serves to transfer the driving current which is output from the driving transistor T2 to the light-emitting diode LED. The gate electrode of the sixth transistor T6 is connected to the light emission control line 155, and the first electrode of the sixth transistor T6 is connected to the second electrode of the driving transistor T2, and the second electrode of the sixth transistor T6 is connected to the anode of the light-emitting diode LED.

The seventh transistor T7 may have p-type transistor characteristics, and may include a polycrystalline semiconductor. The seventh transistor T7 may be positioned on a polycrystalline semiconductor, and include the first silicon oxide film OX1 formed using the remote plasma ashing apparatus while aqueous vapor was supplied. In an embodiment, the seventh transistor T7 may be positioned on the polycrystalline semiconductor and include a second silicon oxide film OX2 which is a native oxide film. In an embodiment, the seventh transistor T7 may include no first silicon oxide film OX1 and no second silicon oxide film OX2.

The seventh transistor T7 serves to initialize the anode of the light-emitting diode LED. The gate electrode of the seventh transistor T7 is connected to the bypass control line 154, and the first electrode of the seventh transistor T7 is connected to the anode of the light-emitting diode LED, and the second electrode of the seventh transistor T7 is connected to the second initialization voltage line 128. When the seventh transistor T7 is turned on by the low voltage of the bypass signal GB, the second initialization voltage AlNT is applied to the anode of the light-emitting diode LED such that the anode is initialized.

Although it has been described above that one pixel includes seven transistors T1 to T7 and one storage capacitor Cst, the present disclosure is not limited thereto, and the number of transistors, the number of capacitors, and the connection relationship of them may be variously changed.

A display device according to an embodiment may be applied to various electronic devices. An electronic device according to an embodiment may include the display device and may further include modules or devices with additional functions other than the display device.

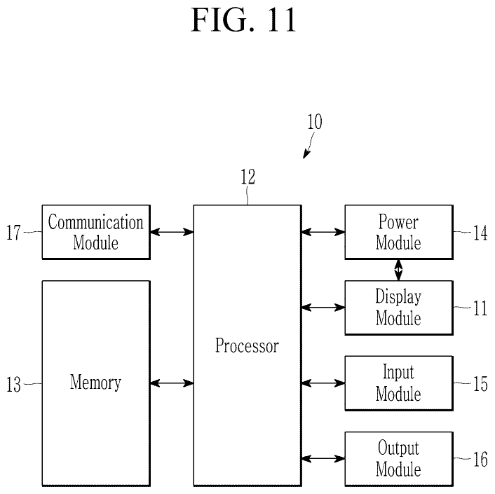

FIG. 11 is a block diagram of an electronic device according to an embodiment. Referring to FIG. 11, an electronic device 10 according to an embodiment may include a display module 11, a processor 12, a memory 13, and a power module 14. The electronic device 10 may further include an input module 14, a non-image output module 15, and/or a communication module 16.

The electronic device 10 can output various information in the form of images through the display module 11. When the processor 12 executes an application stored in the memory 13, it can provide the user with visual information provided by the application through the display module 11. The power module 14 may include a power supply module such as a power adapter or battery device, and a power conversion module that converts the power supplied by the power supply module to generate the power necessary for the operation of the electronic device 10. The input module 14 can provide input information to the processor 12 and/or the display module 11. The non-image output module 15 can receive information other than images from the processor 12, such as sound, haptic, or light information, and provide it to the user. The communication module 16 is responsible for transmitting and receiving information between the electronic device 10 and external devices, and may include a receiver and a transmitter.

At least one of the components of the electronic device 10 may be included in the display device according to the described embodiments. Furthermore, some of the individual modules that are functionally included in one module may be incorporated into the display device, while others may be provided separately from the display device. For example, the display device may include the display module 11, while the processor 12, memory 13, and power module 14 may be provided in the form of other devices within the electronic device 10 that are not part of the display device.

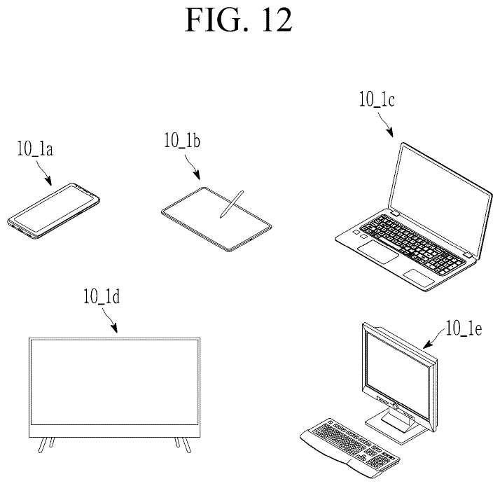

FIGS. 12 to 14 are schematic diagrams of electronic devices according to various embodiments. FIGS. 12 to 14 illustrate examples of various electronic devices to which the display device according to the embodiments is applied.

FIG. 12 illustrates examples of electronic devices, including a smartphone 10_1a, tablet PC 10_1b, laptop 10_1c, TV 10_1d, and desktop monitor 10_1e.

The smartphone 10_1a may include an input module such as a touch sensor and a communication module in addition to the display module 11. The smartphone 10_1a can process information received through the communication module or other input modules and display information through the display module of the display device.

A tablet PC 10_1b, a laptop 10_1c, a TV 10_1d, and a desktop monitor 10_1e may include a display module and an input module similar to a smartphone 10_1a, and may further include a communication module in some cases.

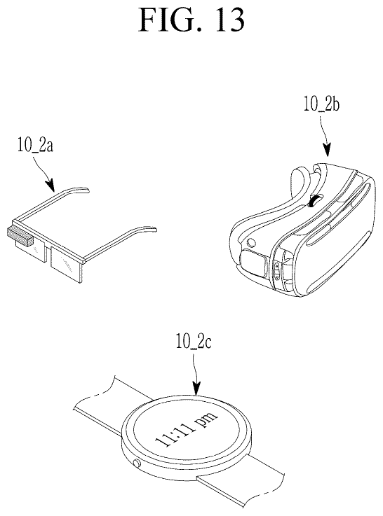

FIG. 13 illustrates an example where an electronic device including a display module is applied to a wearable electronic device. The wearable electronic device may be smart glasses 10_2a, a head-mounted display 10_2b, a smart watch 10_2c, or the like.

The smart glasses 10_2a and head-mounted display 10_2b may include a display module for emitting display images and a reflector for reflecting the emitted display screen to a user's eye, thereby providing virtual reality or augmented reality screens to the user.

The smart watch 10_2c includes a biosensor as an input device and may provide biometric information recognized through the biosensor to the user via the display module.

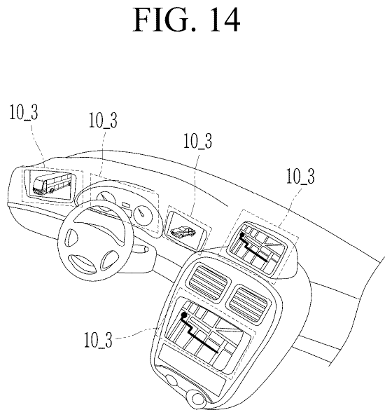

FIG. 14 illustrates an example where an electronic device including a display module is applied to a vehicle. For example, the electronic device 10_3 may be applied to an instrument panel or a center fascia of a vehicle, or may be applied to a CID (Center Information Display) disposed on a dashboard of the vehicle or a room mirror display replacing a side mirror.

Although not illustrated, the electronic device to which the display device according to the embodiments is applied may include not only devices mainly for screen display such as advertisement boards, electronic display boards, and game machines, but also various home appliances that display information through a display module such as refrigerators, washing machines, dryers, air conditioners, and robot vacuum cleaners. Additionally, when the display module has a light transmission function, it may be applied to electronic devices such as smart windows or transparent display devices that display both background and display images. The types of electronic devices according to the embodiments are not limited to the examples described above, and may be applicable to various other electronic devices not exemplified.

While this disclosure has been described in connection with what is presently considered to be practical embodiments, it is to be understood that the inventive concept is not limited to the disclosed embodiments. On the contrary, it is intended to cover various modifications and equivalent arrangements included within the spirit and scope of the appended claims.

What is claimed is:

1. A display device comprising:
a substrate;
a first polycrystalline semiconductor on the substrate and including a channel region, a source region, and a drain region of a first transistor;
a first silicon oxide film on the first polycrystalline semiconductor;
a first gate insulating film on the first silicon oxide film;
a gate electrode of the first transistor on the first gate insulating film and overlapping the channel region of the first transistor; and
a first interlayer insulating film on the gate electrode,
wherein a thickness ratio of the first silicon oxide film and the channel region of the first transistor is 1:13 to 1:16.

2. The display device of claim 1, wherein:
a g value of the first silicon oxide film measured with an electron spin resonance spectrometer is equal to or greater than 2.000 and is smaller than 2.005.

3. The display device of claim 1, wherein:
a dangling bond density of silicon of the first silicon oxide film measured with an electron spin resonance spectrometer is smaller than 1.98×10¹³/cm³.

4. The display device of claim 1, wherein:
a surface of the first silicon oxide film has a surface roughness in which an Rt value is equal to or greater than 40 nm and is smaller than 98 nm and an Rq value is equal to or greater than 8 nm and is smaller than 19 nm.

5. A display device comprising:
a substrate;
a first polycrystalline semiconductor on the substrate and including a channel region, a source region, and a drain region of a first transistor;
a second polycrystalline semiconductor apart from the first polycrystalline semiconductor on the substrate and including a channel region, a source region, and a drain region of a second transistor;
a first silicon oxide film on the first polycrystalline semiconductor;
a second silicon oxide film on the second polycrystalline semiconductor;
a first gate insulating film on the first silicon oxide film and the second silicon oxide film;
a gate electrode of the first transistor on the first gate insulating film and overlapping the channel region of the first transistor;
a gate electrode of the second transistor on the first gate insulating film and overlapping the channel region of the second transistor; and
a first interlayer insulating film on the gate electrode of the first transistor and the gate electrode of the second transistor,
wherein a thickness ratio of the first silicon oxide film and the second silicon oxide film is 1:0.15 to 1:0.4.

6. The display device of claim 5, wherein:
a thickness of the first silicon oxide film is 2.5 nm to 3.0 nm, and
a thickness of the second silicon oxide film is 0.5 nm to 1.0 nm.

7. The display device of claim 5, wherein:
a thickness ratio of the first silicon oxide film and the channel region of the first transistor is 1:13 to 1:16.

8. The display device of claim 5, wherein:
a thickness ratio of the second silicon oxide film and the channel region of the second transistor is 1:42 to 1:84.

9. The display device of claim 5, wherein:
a thickness of the channel region of the first transistor is 40 nm or less, and
a thickness of the channel region of the second transistor is greater than 40 nm and is equal to or smaller than 42 nm.

10. The display device of claim 5, wherein:
a ratio of a first thickness which is a sum of a thickness of the first silicon oxide film and a thickness of the channel region of the first transistor to a second thickness which is a sum of a thickness of the second silicon oxide film and a thickness of the channel region of the second transistor is 0.9:1 to 1.1:1.

11. The display device of claim 5, wherein:
a g value of the first silicon oxide film measured with an electron spin resonance spectrometer is equal to or greater than 2.000 and is smaller than 2.005, and
a g value of the second silicon oxide film measured with the electron spin resonance spectrometer is equal to or greater than 2.005.

12. The display device of claim 5, wherein:
a dangling bond density of silicon of the first silicon oxide film measured with an electron spin resonance spectrometer is smaller than 1.98×10¹³/cm³, and
a dangling bond density of silicon of the second silicon oxide film measured with the electron spin resonance spectrometer is equal to or greater than 1.98×10¹³/cm³.

13. The display device of claim 5, wherein:
a surface of the first silicon oxide film has a surface roughness in which an Rt value is equal to or greater than 40 nm and is smaller than 98 nm and an Rq value is equal to or greater than 8 nm and is smaller than 19 nm.

14. The display device of claim 5, wherein:
the first transistor is a switching transistor, and
the second transistor is a driving transistor.

15. The display device of claim 5, wherein:
the first silicon oxide film is formed by performing plasma processing on a surface of the first polycrystalline semiconductor under conditions of a temperature of 200° C. to 300° C. and 45 sec to 240 sec, using hydrogen and hydroxyl radicals (H⁺ and OH⁺) generated by supplying aqueous vapor (H₂O vapor) to a remote plasma ashing apparatus.

16. The display device of claim 5, wherein:
the second silicon oxide film is a native oxide film of a surface of the second polycrystalline semiconductor.

17. A display device comprising:
a substrate;
a first polycrystalline semiconductor on the substrate and including a channel region, a source region, and a drain region of a first transistor;
a first silicon oxide film on the first polycrystalline semiconductor;
a first gate insulating film on the first silicon oxide film;
a gate electrode of the first transistor on the first gate insulating film and overlapping the channel region of the first transistor;
a first interlayer insulating film on the gate electrode of the first transistor;
an oxide semiconductor on the first interlayer insulating film, and including a channel region, a source region, and a drain region of a third transistor;
a third gate insulating film on the oxide semiconductor;
a gate electrode of the third transistor on the third gate insulating film, and overlapping the channel region of the third transistor; and
a second interlayer insulating film on the gate electrode of the third transistor,
wherein a thickness ratio of the first silicon oxide film and the channel region of the first transistor is 1:13 to 1:16.

18. The display device of claim 17, wherein:
a g value of the first silicon oxide film measured with an electron spin resonance spectrometer is equal to or greater than 2.000 and is smaller than 2.005.

19. The display device of claim 17, wherein:
a dangling bond density of silicon of the first silicon oxide film measured with an electron spin resonance spectrometer is smaller than 1.98×10¹³/cm³.

20. The display device of claim 17, wherein:
a surface of the first silicon oxide film has a surface roughness in which an Rt value is equal to or greater than 40 nm and is smaller than 98 nm and an Rq value is equal to or greater than 8 nm and is smaller than 19 nm.
